(19) United States
(12) Patent Application Publication
(10) Pub. No.: US 2020/0196463 A1
(43) Pub. Date: Jun. 18, 2020

(54) DISPLAY DEVICE

(71) Applicants: K-Tronics (Suzhou) Technology Co., Ltd., Suzhou (CN); BOE Technology Group Co., Ltd., Beijing (CN)

(72) Inventors: Guangning HAO, Beijing (CN); Tao NI, Beijing (CN); Yaojun SUN, Beijing (CN)

(21) Appl. No.: 16/454,665

(22) Filed: Jun. 27, 2019

(30) Foreign Application Priority Data
Dec. 18, 2018 (CN) 201822133830.8

(51) Int. Cl. H05K 5/02; H05K 5/00

(52) U.S. Cl. CPC H05K 5/0204; H05K 5/0017

(57) ABSTRACT

A display device includes a display and a wall mount for fixing the display. The wall mount includes a first connection member and a second connection member. The first connection member is configured to support the display, the second connection member is provided on the display, thereby the whole display is attached to the wall fixedly with magnetic attraction between the first connection member and the second connection member.

### CROSS-REFERENCE TO RELATED APPLICATION

This application claims the priority to the Chinese patent application No. 201822133830.8 filed on Dec. 18, 2018, the disclosure of which is incorporated herein in its entirety by reference.

### TECHNICAL FIELD

The present disclosure relates to the field of display technology, and particularly relates to a display device.

### BACKGROUND

As shown in FIG. 1, in the related technology, members of a television set 10 such as a main board, a power panel, a horn etc. are usually fixed at a lower portion of a backboard of the television set. Thus it needs to form a protruding region 20 in the lower portion of the backboard to accommodate the above members. Since the protruding region 20 occupies a lower back space of the television set 10, the television set is not suitable for hanging from a wall, but mostly for support on a TV base.

In order to improve a whole effect of the television set being hung from a wall and reduce a distance between the wall hanging television set and the wall, the protruding region at the back is removed in some designs of the television set, such that the whole back of the television set becomes a large plane, and such a liquid crystal television is usually known as “wall-mounted television”.

### SUMMARY

A display device includes a display and a wall mount for fixing the display, the wall mount including at least one first connection member configured to support the display and at least one second connection member on the display, and the first connection member and the second connection member attract each other with magnetic attraction.

According to embodiments of the present disclosure, one of the first connection member and the second connection member is made of a magnetic material, and the other is made of a material which is attracted by the magnetic material.

According to embodiments of the present disclosure, the first connection member is made of a metal that is attracted by the magnetic material, and the second connection member is made of the magnetic material.

According to embodiments of the present disclosure, the first connection member includes a strip-shaped wallboard and a support portion for supporting a bottom of the display, and the support portion is connected with a first end of the strip-shaped wallboard.

According to embodiments of the present disclosure, the display includes a main body, and the second connection member is provided on the main body.

According to embodiments of the present disclosure, a rear case is provided at a side of the display distal to a light-outgoing surface, and the second connection member is provided on the rear case.

According to embodiments of the present disclosure, the at least one first connection member and the at least one second connection member are provided in one-to-one correspondence, and a projection of the second connection member on a plane where the strip-shaped wallboard of the corresponding first connection member is located at least partially overlaps with the strip-shaped wallboard of the corresponding first connection member.

According to embodiments of the present disclosure, the second connection member includes a magnetic strip.

According to embodiments of the present disclosure, a rear case is provided at a side of the display distal to a light-outgoing surface, the rear case is made of a magnetic material, and functions as the second connection member.

According to embodiments of the present disclosure, the at least one first connection member includes at least one first connection sub-member and at least one second connection sub-member, the first connection sub-member is configured to support the display, the second connection sub-member is made of a material which is attracted by a magnetic material, and the second connection member is made of a magnetic material.

According to embodiments of the present disclosure, the at least one second connection member and the at least one second connection sub-member are provided in one-to-one correspondence, and a projection of the second connection member on a plane where the corresponding second connection sub-member is located at least partially overlaps with the corresponding second connection sub-member.

According to embodiments of the present disclosure, the at least one second connection sub-member is evenly distributed in a projection area of the display on a plane where the at least one second connection sub-member is located.

According to embodiments of the present disclosure, the support portion includes a hook which has a bending portion towards a second end of the strip-shaped wallboard along an extending direction of the strip-shaped wallboard, and the bottom of the display has a groove fitted with the hook.

According to embodiments of the present disclosure, the strip-shaped wallboard is integrally formed with the support portion.

According to embodiments of the present disclosure, a through-hole is provided in the strip-shaped wallboard to mount the strip-shaped wallboard fixedly.

According to embodiments of the present disclosure, a through-hole is provided in the strip-shaped wallboard to mount the strip-shaped wallboard fixedly, and a through-hole is provided in the second connection sub-member to mount the second connection sub-member fixedly.

### BRIEF DESCRIPTION OF DRAWINGS

FIG. 1 is a structural schematic diagram of a related television set;

FIG. 2 is a structural schematic diagram of a display device according to embodiments of the present disclosure;

FIG. 3 is one kind of structural schematic diagram of a display device according to embodiments of the present disclosure;

FIG. 4 is a structural schematic diagram of a second connection member of a display device according to embodiments of the present disclosure;

FIG. 5 is a side view of a second connection member of a display device according to embodiments of the present disclosure;

FIG. 6 is a partial structural schematic diagram of a display device according to embodiments of the present disclosure;

FIG. 7 is a partial structural side view of a display device according to embodiments of the present disclosure;

FIG. 8 is a stereoscopic structural schematic diagram of a display device according to embodiments of the present disclosure;

FIG. 9 is a partial installation schematic diagram of a display device according to embodiments of the present disclosure; and

FIG. 10 is a structural schematic diagram of a display device according to embodiments of the present disclosure.

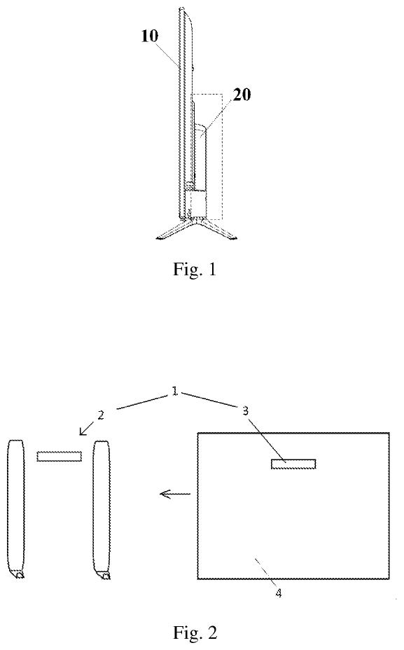

### DETAILED DESCRIPTION

In order to make a person skilled in the art better understand the technical solution of the present disclosure, the present disclosure will be further illustrated in detail below in conjunction with accompanying drawings and embodiments.

When a wall-mounted television set is hung from a wall, it needs a mating wall-hanging rack. As for a conventional wall-hanging rack, one part of the rack is fixed on a liquid crystal television, and another part of the rack is attached to a wall. Usually the wall-hanging rack needs to occupy a space of about 20 to 40 mm in a direction perpendicular to the liquid crystal display plane. That is, the existence of the wall-hanging rack causes a greater distance between the television set and the wall, and affects aesthetic sense of the television significantly. Therefore, how to make the television set fit to the wall totally or approximately has become a major problem in the art.

According to embodiments of the present disclosure, a display device provided, as shown in FIG. 2, includes a display 4 and a wall mount 1 for fixing the display 4. The wall mount 1 includes at least one first connection member 2 and at least one second connection member 3. The first connection member 2 is configured to be fixed to the wall, so as to support the display 4. The second connection member 3 is configured to be provided on the display 4, and the first connection member 2 and the second connection member 3 attract each other with magnetic attraction.

In this embodiment, the first connection member 2 in the wall mount 1 functions as supporting the display 4 upward in an opposite direction to gravity, and the first connection member 2 is mounted on the wall fixedly. The second connection member 3 is provided on the display 4. The display 4 is attached to the wall as a whole fixedly under magnetic attraction between the first connection member 2 and the second connection member 3. The wall mount 1 is simple, occupies a small exterior space, and is beneficial for the display 4 approximately fitted close to the wall. The wall mount 1 is applicable to various kinds of display 4, especially the wall-mounted liquid crystal television, and ensures the wall-mounted liquid crystal television is fitted to the wall surface to a maximum extent.

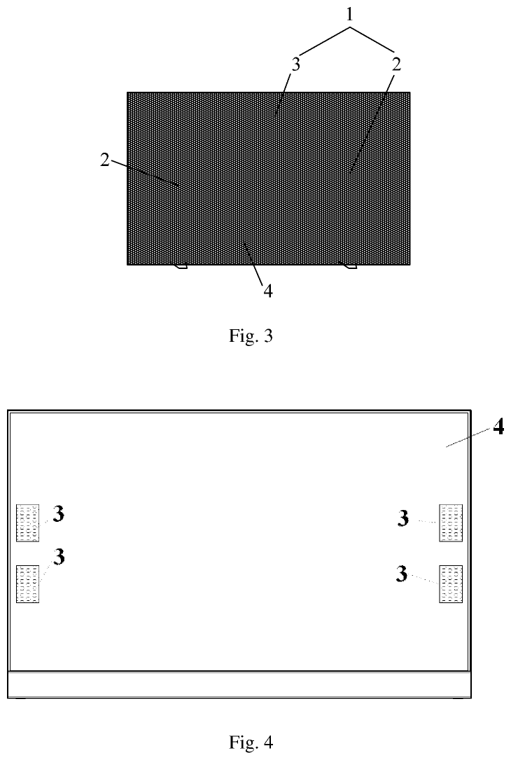

According to embodiments of the present disclosure, a display device provided, as shown in FIGS. 3-9, includes a display 4 and a wall mount 1 for fixing the display 4. The wall mount 1 includes at least one first connection member 2 and at least one second connection member 3. As shown in FIG. 3, the first connection member 2 is configured to be fixed to the wall, so as to support the display 4. The second connection member 3 is configured to be disposed on the display 4. One of the first connection member 2 and the second connection member 3 is made of a magnetic material, the other is made of a metal, for example, iron which can be attracted by the magnetic material. The first connection member 2 and the second connection member 3 attract each other with magnetic attraction.

In this embodiment, materials for making the first connection member 2 and the second connection member 3 are not defined, as long as magnetic attraction exists between them, that is, the first connection member 2 and the second connection member 3 are connected to each other fixedly by magnetic attraction, so as to fix the display 4 on the wall.

In one embodiment, the first connection member 2 may be made of a metal, for example, iron, and the second connection member 3 may be made of a magnetic material. The first connection member 2 and the second connection member 3 attract each other with magnetic attraction. In this embodiment, numbers or sizes of the first connection member 2 and the second connection member 3 are not defined, and may be adjusted or changed according to area or weight of the display 4.

In one embodiment, as shown in FIGS. 6-9, the first connection member 2 includes a strip-shaped wallboard 11 and a support portion 12 for supporting a bottom of the display 4, and the support portion 12 is connected with a first end of the strip-shaped wallboard 11. The strip-shaped wallboard 11 functions to be fixed on the wall, and the support portion 12 functions to support the display 4 from the bottom up, and to bear weight of the display 4.

Since the display 4 has a relatively large area, an upper portion of the display 4 cannot be ensured stable by merely supporting the display 4 from a lower portion. In some embodiments, the second connection member 3 is provided on the upper portion of the display 4, and attracts the upper portion of the wall-hanging display 4 to the first connection member 2. That is, on the upper rear of the display 4, the display 4 may be attracted onto the wall stably with the mutual attraction between the first connection member 2 and the second connection member 3, so as to prevent the display 4 from separating from the wall.

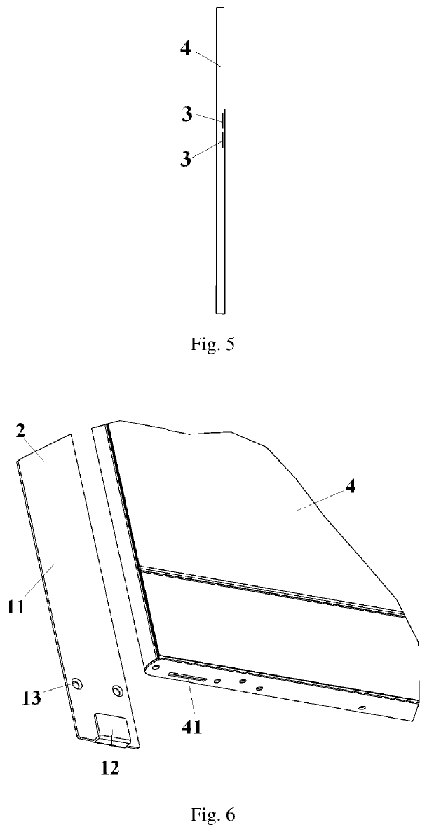

It should be noted that the second connection member 3 may be provided on a main body of the display 4 as shown in FIG. 4, or may be provided inside the main body of the display 4 as shown in FIG. 5. For example, the second connection member 3 may be provided at a position such as a gap bounded by a bending edge of a reflector plate and a backboard at a side of an internal structure of the main body of the display 4. In addition, the whole backboard on the rear of the display 4 may be made of the above-mentioned magnetic material or iron as long as the second connection member 3 is provided at a position corresponding to the first connection member 2, thereby fixing the display 4 by the mutual attraction of the second connection member 3 and the first connection member 2. All these methods can reduce space occupied by the wall-hanging structure.

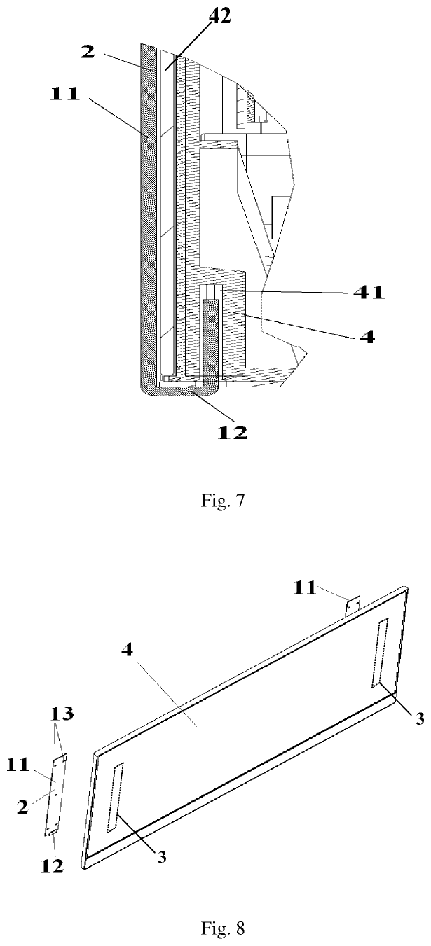

In one embodiment, a rear case 42 is provided at a side of the display 4 distal to a light-outgoing surface, and the second connection member 3 is provided on the rear case 42, as shown in FIG. 7. To be specific, the second connection member 3 can also be provided either on an upper portion of an interior side of the rear case 42 or an upper portion of an external side of the rear case 42. It is also possible to integrate the rear case 42 with the second connection member 3, that is, the rear case 42 is provided to be made of the magnetic material directly, serving as the second connection member 3.

In one embodiment, the support portion 12 includes a hook, as shown in FIG. 6. The hook has a bending portion towards a second end of the strip-shaped wallboard 11 along an extending direction of the strip-shaped wallboard 11, and the bending portion is used for inserting into the bottom of the display 4.

That is, as shown in FIGS. 6-9, in this embodiment, the support portion 12 is in a form of hook to be closely combined with the display 4, so as to support the display 4.

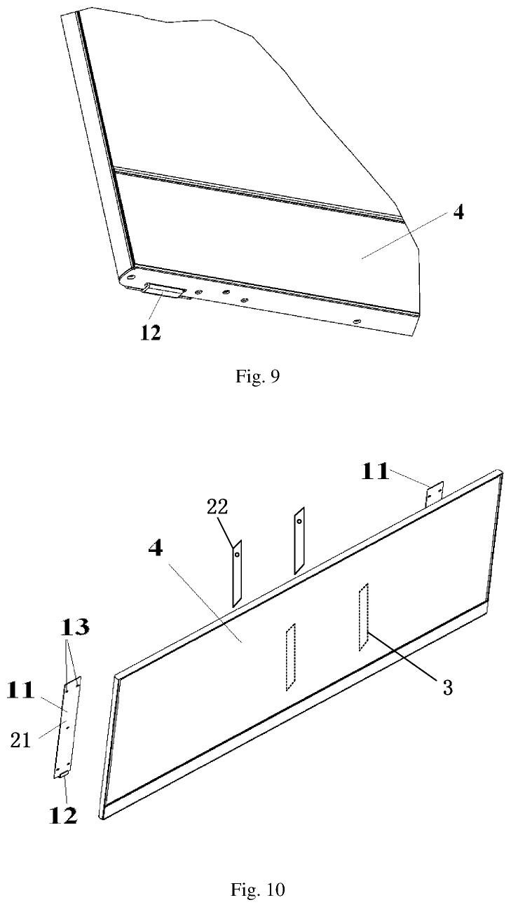

In one embodiment, the bottom of the wall-hanging display 4 has an inwardly-concaved groove 41 fitted to the hook when hanging the display 4. The hook is inserted into the groove 41, which is shown in FIG. 9 after being assembled.

In this embodiment, when hanging the display 4, a side of the light-outgoing surface of the display 4 close to ground along the vertical direction is the bottom, and the groove 41 is dented at the bottom of the display 4 towards a side departing from ground, as shown in FIGS. 6-7. In this embodiment, the groove 41 is provided on both sides of the bottom of the display 4, such that it prevents blind assembling and has less installation difficulty.

In one embodiment, the strip-shaped wallboard 11 is vertically provided, and the hook is connected to a bottom end of the strip-shaped wallboard 11, that is, a first end of the strip-shaped wall panel 11 near the ground when hanging the strip-shaped wallboard 11.

In this embodiment, the strip-shaped wallboard 11 is made of the magnetic material or iron, that is, the strip-shaped wallboard 11 also functions as the first connection member 2, and has advantages of simple hanging-structure, easy installation and good-looking appearance.

In some embodiments, the strip-shaped wallboard 11 is integrally formed with the support portion 12. That is, the strip-shaped wallboard 11 and the support portion 12 (including the hook) are integrally formed, which can ensure the first connection member 2 more solid and more stable. It can be understood that the strip-shaped wallboard 11 may be made of iron, and serves as the first connection member 2, the second connection member 3 on the display 4 is provided at a position corresponding to the strip-shaped wallboard 11.

In some embodiments, there are at least two first connection members 2. To be specific, two or more strip-shaped wallboards 11 are evenly arranged on the wall at the back of the display 4 to evenly bear the weight of the display 4.

In this embodiment, fixing ways for fixing the strip-shaped wallboard 11 on the wall are not defined, that is, the strip-shaped wallboard 11 may be fixed on the wall by multiple joining ways. In an embodiment, as shown in FIG. 6, the strip-shaped wallboard 11 is provided with at least one through-hole 13. The strip-shaped wallboard 11 can be mounted on the wall fixedly via a screw fitted to the through-hole 13 on the first connection member 2. That is, the strip-shaped wallboard 11 is fixed on the wall via the screw passing through the through-hole 13 in the strip-shaped wallboard 11. The numbers or size of the through-holes 13 as well as positions of the through-holes 13 can be designed or improved according to sizes of the display 4 and the strip-shaped wallboard 11.

In an embodiment, the at least one first connection member 2 and the at least one second connection member 3 are provided in one-to-one correspondence, and a projection of the second connection member 3 on a plane where the strip-shaped wallboard 11 of the corresponding first connection member 2 is located at least partially overlaps with the strip-shaped wallboard 11 of the corresponding first connection member 2, as shown in FIG. 8. That is, the first connection member 2 and the second connection member 3 is at least partially provided face to face, which can increase the magnetic attraction.

In one embodiment, the second connection member 3 includes a plurality of magnetic strips. When hanging the display 4, an orthogonal projection of the magnetic strips on a plane where the strip-shaped wallboard 11 of the corresponding first connection member 2 is located at least partially overlaps with the corresponding strip-shaped wallboard 11. In some embodiments, the magnetic strips have the same size as the strip-shaped wallboard 11.

That is, the second connection member 3 in this embodiment have a corresponding shape to the strip-shaped wallboard 11, which can be a similar strip shape, so as to be suitable for mutual attraction with the strip-shaped wallboard 11 and make the display 4 more stable.

In this embodiment, the strip-shaped wallboard 11 is made of iron, and brings advantages of simple hanging-structure, easy installation and good-looking appearance.

In another embodiment, the first connection member 2 includes a first connection sub-member 21 and a second connection sub-member 22. The first connection sub-member 21 is configured to support the display 4, as shown in FIG. 10. The second connection sub-member 22 is made of a material which can be attracted by a magnetic material, and the second connection member 3 is made of the magnetic material.

The second connection sub-member 22 and the second connection member 3 on the display 4 attract each other with magnetic attraction. To be specific, the strip-shaped wallboard 11 of the first connection sub-member 21 may be made of a non-metallic material, and is provided at an edge position at rear of the display 4 for mechanical fixation only.

The second connection sub-member 22 can be provided on the wall and at any position in the projection area of the display 4 on a plane where the second connection sub-member 22 is located, for example, the second connection sub-member 22 can be evenly provided corresponding to four edge positions at rear of the display 4, or corresponding to an middle position at rear of the display 4. In one embodiment, the second connection member 3 and the second connection sub-member 22 are provided in one-to-one correspondence, and a projection of the second connection member 3 on a plane where the corresponding second connection sub-member 22 is located at least partially overlaps with the corresponding second connection sub-member 22, so it can increase the magnetic attraction. When there are a plurality of the second connection sub-members 22 in the wall mount, the plurality of the second connection sub-members 22 are evenly distributed within a projection area of the display 4 on a plane where the second connection sub-members 22 are located, so that the display 4 may be evenly attracted on its rear in all directions, so as to hang the display 4 on the wall surface stably.

As shown in FIG. 10, in one embodiment, the first connection sub-member 21 includes a strip-shaped wallboard 11 and a support portion 12 for supporting a bottom of the display 4, and the support portion 12 is connected with a first end of the strip-shaped wallboard 11. The strip-shaped wallboard 11 functions to be fixed on the wall, and the support portion 12 functions to support the display 4 from the bottom up, and to bear the weight of the display 4. The support portion 12 includes a hook. The hook has a bending portion towards a second end of the strip-shaped wallboard along an extending direction of the strip-shaped wallboard, and the bottom of the display has a groove fitted to the hook, as shown in FIG. 6. The strip-shaped wallboard 11 is integrally formed with the support portion 12. The strip-shaped wallboard 11 is provided with the through-hole 13 so as to mount the strip-shaped wallboard 11 fixedly, and the second connection sub-member 22 is provided with a through-hole so as to mount the second connection sub-member 22 fixedly.

In this embodiment, the display may be any products or members having a display function such as a liquid crystal display panel, an electronic paper, an OLED panel, a mobile phone, a tablet computer, a television set, a display, a laptop, a digital camera, a navigator, etc.

In an embodiment, the display device assembly can ensure the display is totally fitted close to a wall surface, and achieve excellent mounting strength with magnetic attraction on the upper portion and a hook mode on the bottom portion.

It should be understood that the above embodiments are merely exemplary embodiments for the purpose of illustrating the principle of the disclosure, and the disclosure is not limited thereto. Various modifications and improvements can be made by a person having ordinary skill in the art without departing from the spirit and essence of the disclosure. Accordingly, all of the modifications and improvements also fall into the protection scope of the disclosure.

1. A display device comprising a display and a wall mount for fixing the display, the wall mount comprising:
at least one first connection member configured to support the display; and
at least one second connection member on the display, wherein the first connection member and the second connection member attract each other with magnetic attraction,
wherein the first connection member comprises a strip-shaped wallboard and a support portion for supporting a bottom of the display, and the support portion is connected with a first end of the strip-shaped wallboard.

2. The display device according to claim 1, wherein one of the first connection member and the second connection member is made of a magnetic material, and the other is made of a material which is attracted by the magnetic material.

3. The display device according to claim 2, wherein the first connection member is made of a metal that is attracted by the magnetic material, and the second connection member is made of the magnetic material.

4. (canceled)

5. The display device according to claim 1, wherein the display comprises a main body, and the second connection member is provided on the main body.

6. The display device according to claim 1, wherein a rear case is provided at a side of the display distal to a light-outgoing surface, and the second connection member is provided on the rear case.

7. The display device according to claim 5, wherein the at least one first connection member and the at least one second connection member are provided in one-to-one correspondence, and a projection of the second connection member on a plane where the strip-shaped wallboard of the corresponding first connection member is located at least partially overlaps with the strip-shaped wallboard of the corresponding first connection member.

8. The display device according to claim 7, wherein the second connection member comprises a magnetic strip.

9. The display device according to claim 1, wherein a rear case is provided at a side of the display distal to a light-outgoing surface, the rear case is made of the magnetic material, and functions as the second connection member.

10. The display device according to claim 1, wherein
the at least one first connection member comprises at least one first connection sub-member and at least one second connection sub-member, the first connection sub-member is configured to support the display, the second connection sub-member is made of a material which is attracted by a magnetic material, and
the second connection member is made of the magnetic material.

11. The display device according to claim 10, wherein the at least one second connection member and the at least one second connection sub-member are provided in one-to-one correspondence, and a projection of the second connection member on a plane where the corresponding second connection sub-member is located at least partially overlaps with the corresponding second connection sub-member.

12. The display device according to claim 11, wherein the at least one second connection sub-member is evenly distributed in a projection area of the display on a plane where the at least one second connection sub-member is located.

13. The display device according to claim 12, wherein the first connection sub-member comprises a strip-shaped wallboard and a support portion for supporting a bottom of the display, and the support portion is connected with a first end of the strip-shaped wallboard.

14. The display device according to claim 13, wherein the second connection member comprises a magnetic strip.

15. The display device according to claim 8, wherein the support portion comprises a hook which has a bending portion towards a second end of the strip-shaped wallboard along an extending direction of the strip-shaped wallboard, and the bottom of the display has a groove fitted with the hook.

16. The display device according to claim 14, wherein the support portion comprises a hook which has a bending portion towards a second end of the strip-shaped wallboard along an extending direction of the strip-shaped wallboard, and the bottom of the display has a groove fitted with the hook.

17. The display device according to claim 15, wherein the strip-shaped wallboard is integrally formed with the support portion.

18. The display device according to claim 16, wherein the strip-shaped wallboard is integrally formed with the support portion.

19. The display device according to claim 17, wherein a through-hole is provided in the strip-shaped wallboard to mount the strip-shaped wallboard fixedly.

20. The display device according to claim 18, wherein a through-hole is provided in the strip-shaped wallboard to mount the strip-shaped wallboard fixedly, and a through-hole is provided in the second connection sub-member to mount the second connection sub-member fixedly.
